(19) United States
(12) Patent Application Publication
(10) Pub. No.: US 2024/0106010 A1
(43) Pub. Date: Mar. 28, 2024

(54) Artificial Solid-Electrolyte Interphase Layer Material and Uses Thereof

(71) Applicant: HeiQ Materials AG, Schlieren (CH)

(72) Inventors: Kyoungjun Choi, Thalwil (CH); Murray J. Height, Newtown (AU)

(21) Appl. No.: 18/273,401

(22) PCT Filed: Mar. 3, 2022
(86) PCT No.: PCT/EP2022/055347

§ 371 Date: Jul. 20, 2023

(30) Foreign Application Priority Data
Mar. 4, 2021 (EP) 21160707.2

(51) Int. Cl. H01M 10/42; H01M 4/04; H01M 4/139; H01M 4/66; H01M 10/052; H01M 10/054

(52) U.S. Cl. CPC H01M 10/4235; H01M 4/0404; H01M 4/0428; H01M 4/139; H01M 4/661; H01M 10/052; H01M 10/054; H01M 2004/027

(57) ABSTRACT

Li or Na based battery having an anode (or current collector) at least partially covered on its side facing the electrolyte by at least one artificial solid-electrolyte interphase layer with at least one layer of porous graphene of a thickness of less than 25 nm with pores having an average characteristic width in the range of 1-1000 nm.

### CROSS REFERENCE TO RELATED APPLICATIONS

This application is the United States national phase of International Application No. PCT/EP2022/055347 filed Mar. 3, 2022, and claims priority to European Patent Application No. 21160707.2, filed Mar. 4, 2021, the disclosures of which are hereby incorporated by reference in their entireties.

### BACKGROUND OF THE INVENTION

### Field of the Invention

The present invention relates to the field of lithium-metal and sodium-metal batteries, including e.g. lithium solid-state batteries. It more particularly relates to solving the problem with dendrite forming in charging and discharging processes. It relates to artificial 2D solid electrolyte interphase layers as well as uses of such layers and methods for making such layers and/or lithium-metal or sodium-metal batteries using such layers.

### DESCRIPTION OF RELATED ART

With the advent of portable electronic devices, and even more so with increasing electric mobility there is an increasing need for high-capacity and long lasting electric energy storage devices.

At present the vast majority of high-capacity rechargeable batteries are provided as first-generation lithium-ion batteries having a liquid electrolyte. The problem of these rechargeable batteries is that the carbon anode limits the available energy density. Liquid electrolyte systems can also present safety challenges. Furthermore the corresponding batteries show slow charging properties due to rate-limiting diffusion properties.

Some enhancements could be achieved by using a graphite-silicon composite anode to increase energy density, but still there is the problem with the increased volume required due to the addition of silicon and the resulting slow charging due to decreased diffusion rates.

The solution to this problem is seen in the provision of so-called lithium-metal batteries, where the graphite and/or graphite-silicon composite is replaced by a lithium metal due to its high specific capacity (3860 mAh g⁻¹). Lithium-metal batteries are anticipated to show a higher energy density, faster charging and a longer lifespan. The anode material of such lithium-metal batteries can be provided in the form of an elemental metal, for example in the form of a lithium layer or foil, allowing for a high energy density, fast charging, low costs and long lifespan. The cathode can be provided in the form of transition metal oxide, sulphur or air. The electrolytes can for example take the form of either non-aqueous solutions or solid-state materials showing appropriate ion diffusion properties.

The problem of using lithium-metal battery technology is the progressive formation of lithium dendrite structures causing rapid degradation of capacity and performance. In the charging process deposition of elemental lithium on the anode, whether this is an elemental lithium anode or anode made of a different material acting as current collector, typically leads to the formation of dendritic structures which either lead to safety issues because the dendrites can penetrate a separator and even contact the cathode leading to short circuit situations, charging and discharging cycles can lead to disconnection of fractions of the dendritic structures leading to dead lithium zones which are not available for future cycles reducing lifespan, and dendrite formation may lead to increasing surface area and/or volume expansion. These problems also appear if so called anode-free battery technology is used, wherein there is no elemental lithium anode, but the anode includes another metal layer as a current collector, for example a copper layer. For these anode-free constructions, there is no excess lithium and corresponding lower costs, and manufacturing processes can be simplified.

Several approaches have been tried to avoid dendrite formation in the systems. Approaches can be grouped into electrolyte engineering, use of a 3D host, separation modification, and artificial solid-electrolyte interphase optimisation. Artificial solid-electrolyte interphase systems should have a high mechanical stability to suppress dendritic lithium growth, they should show electrochemical stability and preferably themselves should be non-conducting, and they should have a high and spatially uniform ionic conductivity not only at room temperature but also under typical operating temperatures of the final battery.

In the past for such artificial solid-electrolyte interphase layers inorganic materials deposited on the anode (e.g., lithium) or the current collector have been proposed in the form of lithium fluoride, lithium phosphate, boron nitride systems or aluminium oxide. Also polymer deposition has been tried, inorganic and organic compound layers, as well as metal nano wire networks. However the systems tried so far show rather low ionic conductivity under typical operation conditions (temperatures), they show a large interfacial impedance and the layers need to be rather thick.

US-A-2021057751 provides an electrode having a carbon-based structure with a plurality of localized reaction sites. An open porous scaffold is defined by the carbon-based structure and can confine an active material in the localized reaction sites. A plurality of engineered failure points is formed throughout the carbon-based structure and can expand in a presence of volumetric expansion associated with polysulfide shuttle. The open porous scaffold can inhibit a formation of interconnecting solid networks of the active material between the localized reaction sites. The plurality of engineered failure points can relax or collapse during an initial activation of the electrode. The open porous scaffold can define a hierarchical porous compliant cellular architecture formed of a plurality of interconnected graphene platelets fused together at substantially orthogonal angles. The hierarchical porous compliant cellular architecture can be expansion-tolerant and can expand in a presence of Li ion insertion or de-insertion.

US-A-2016301075 discloses a dendrite penetration-resistant layer for a rechargeable alkali metal battery, comprising multiple graphene sheets or platelets or exfoliated graphite flakes that are chemically bonded by a lithium- or sodium-containing species to form an integral layer that prevents dendrite penetration through the integral layer, wherein the lithium-containing species is selected from a specific group of compounds. Also provided is a process for producing a dendrite penetration-resistant layer based on the principle of electrochemical decomposition of an electrolyte in the presence of multiple graphene sheets.

US-A-2020328404 discloses electrochemical systems and related methods of making and using electrochemical systems. Electrochemical systems of the invention implement novel cell geometries and composite carbon nanomaterials based design strategies useful for achieving enhanced electrical power source performance, particularly high specific energies, useful discharge rate capabilities and good cycle life. Electrochemical systems of the invention are versatile and include secondary lithium ion cells, useful for a range of important applications including use in portable electronic devices.

CN-A-107871868 provides a graphene-enhanced integrated electrode, which comprises a conductive material linear structural body, an active material linear structural body, and a graphene layer growing in situ on the surface of the conductive material linear structural body and/or active material linear structural body, wherein the conductive material linear structural body and active material linear structural body interpenetrate in a three-dimensional space to form a linear network structure, and the graphene layer connects the two linear structural bodies to form an integrated three-dimensional linear network integral body, which has network gaps. The conductive material linear structural body is made from a current collector having an electron collection function, and the active material linear structural body is made from a material for energy storage via ion de-intercalation. The integrated electrode can efficiently improve the stress interface formed between an electrode active material and the current collector, and is high in energy density and circulation stability. The invention further provides a preparation method of the integrated electrode and a battery comprising the integrated electrode.

CN-A-103794791 provides a continuous-phase spongy graphene material. The core part of the material is provided with a foamed nickel substrate; the outer surface of the foamed nickel substrate is coated with graphene obtained by a CH4 gas via CVD (chemical vapor deposition); the graphene material is integrated continuous-phase spongy block graphene. The invention also provides two preparation methods of the continuous-phase spongy graphene material, wherein one preparation method provided by the invention is characterized in that the preparation material is the continuous-phase spongy graphene material two end surfaces of which are not provided with graphene, and can serve as the positive electrode or the negative electrode material of a lithium ion battery, and the advantages of maximum current carrier, favorable cycle stability, good heat conduction, rapid electric conduction, increase of electrolyte contact surface, and volume conservation can be realized; the other preparation method provided by the invention is characterized in that the preparation material is an integral continuous-phase spongy graphene heat radiation material, serves as a heat radiation material of heat radiation devices of a computer CPU, an LED light source, a tablet personal computer, a mobile phone and the like, and has better heat conduction and heat radiation effects compared with a traditional heat radiation material.

US-A-2017352869 discloses a lithium or sodium metal battery having an anode, a cathode, and a porous separator and/or an electrolyte, wherein the anode contains a graphene-metal hybrid foam composed of multiple pores, pore walls, and a lithium- or sodium-attracting metal residing in the pores; wherein the metal is selected from Au, Ag, Mg, Zn, Ti, Na (or Li), K, Al, Fe, Mn, Co, Ni, Sn, V, Cr, or an alloy thereof and is in an amount of 0.1% to 90% of the total hybrid foam weight or volume, and the pore walls contain single-layer or few-layer graphene sheets, wherein graphene sheets contain a pristine graphene or non-pristine graphene selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof.

Kumar et al. in NanoResearch, 2019, 12(11): 2655-2694 (https://doi.org/10.1007/s12274-019-2467-8) report that the significance of graphene and its two-dimensional (2D) analogous inorganic layered materials especially as hexagonal boron nitride (h-BN) and molybdenum disulphide (MoS2) for “clean energy” applications became apparent over the last few years due to their extraordinary properties. In this review article the progress and selected challenges in the syntheses of graphene, h-BN and MoS2 including energy storage applications as supercapacitors and batteries is studied. Various substrates/catalysts (metals/insulator/semiconducting) have been used to obtain graphene, h-BN and MoS2 using different kinds of precursors. The most widespread methods for synthesis of graphene, h-BN and MoS2 layers are reported to be chemical vapor deposition (CVD), plasma-enhanced CVD, hydro/solvothermal methods, liquid phase exfoliation, physical methods etc. Current research has shown that graphene, h-BN and MoS2 layered materials modified with metal oxide can have an insightful influence on the performance of energy storage devices as supercapacitors and batteries. This review article also contains the discussion on the opportunities and perspectives of these materials (graphene, h-BN and MoS2) in the energy storage fields.

US-A-2019168485 discloses a method for making a porous graphene layer of a thickness of less than 100 nm with pores having an average size in the range of 5-900 nm, includes the following steps: providing a catalytically active substrate catalyzing graphene formation under chemical vapor deposition conditions, the catalytically active substrate in or on its surface being provided with a plurality of catalytically inactive domains having a size essentially corresponding to the size of the pores in the resultant porous graphene layer; chemical vapor deposition using a carbon source in the gas phase and formation of the porous graphene layer on the surface of the catalytically active substrate. The pores in the graphene layer are in situ formed due to the presence of the catalytically inactive domains.

### SUMMARY OF THE INVENTION

It is therefore an object of the present invention to provide an artificial solid-electrolyte interphase layer in the form of a two-dimensional layer which is electrochemically stable against chemicals either in liquid or solid electrolytes, where the electrolyte (lithium, or sodium) in its ion form can diffuse through the layer, which is mechanically stable to suppress the growth of dendrite structures of lithium or sodium, and which is flexible and stretchable to bear the volume exchange of lithium/sodium. Furthermore the two-dimensional material shall prevent direct contact between lithium/sodium metal and electrolyte or poly sulphide.

According to one of the key elements of the present invention, an artificial solid-electrolyte interphase layer in the form of a porous graphene layer is suggested. It could be shown that using such porous graphene layers covering anode material (including the situation where the anode is a current collector) and interfacing between the anode and/or current collector and the liquid or solid electrolyte portion, can prevent lithium dendrite formation and provide an interphase layer providing at least one or a combination or even all of the above advantages. Also as a thin two-dimensional layer, the porous graphene is light and adds negligible volume, which are beneficial to an enhancement of energy density.

According to a first aspect of the present invention therefore a Li or Na based, e.g. solid-state, battery it is proposed having an anode (the expression “anode” including the situation where it is given by a current collector, the material of which does not participate in the electrochemical process but only acts as a current conductor; typically the “anode” according to this disclosure can be a lithium layer but can also be a layer of an alloy thereof or another metal layer) at least partially covered on its side facing the electrolyte (which can be a liquid or solid state electrolyte) by at least one artificial solid-electrolyte interphase layer with at least one layer of porous graphene of a thickness of less than 25 nm preferably with pores having an average characteristic width as defined in the specification in the range of 1-1000 nm.

The porous graphene layer according to the present invention is to be understood as a contiguous layer having passage openings in the form of the mentioned pores. It is not to be equated with a graphene layer comprising or consisting of a number of platelets, flakes and/or grains of graphene forming a coherent structure and between which there are interstitial spaces, since in this case the graphene layer is not a contiguous layer but actually an assembly of individual graphene elements.

Also the porous graphene layer according to the present invention is not to be equated with a sponge or spongy structure, as the latter is not only porous but actually comprises a three-dimensional skeleton and correspondingly is also absorbent in the sense that it actually takes up and absorbs material in internal cavities of the porosity formed by the skeleton. The porous graphene layer according to the present invention is essentially a two-dimensional planar structure with pores within the planar layer which is not absorbing and is not a three-dimensional skeleton. Furthermore the topology of the planar layer of the present invention is such that it may be separated from the supporting substrate as a single contiguous layer in contrast to a graphene layer supported on a spongy structure where the graphene layer cannot be separated from the substrate as a single contiguous layer due to topological interpenetration of the sponge network within the graphene structure.

The through openings forming the pores can have variable shape; normally they take the form of oval, round, but also of elongate shapes which can be linear or branched.

Using such an interphase layer fast charging is possible and a high energy density can be achieved. Typically it is sufficient to have one such porous graphene layer in that artificial solid-electrolyte interphase layer, which can be supplemented by an additional non-porous graphene layer as will be detailed further below.

According to a first preferred embodiment of the proposed battery, the artificial solid-electrolyte interphase layer, preferably the porous graphene layer, has a thickness in the range of 1-15 nm, preferably in the range of 5-10 nm.

The porous graphene layer preferably has an areal porosity in the range of at least 10%, preferably at least 15%, more preferably of at least 20% or at least 25% or at least 30% or at least 40%.

Further preferably, said porous graphene has pores having an average characteristic width in the range of 5-900 nm.

The average characteristic width of the pores is defined and measured as follows:

As the shape of the pores are generally elongated and uneven it is challenging to obtain the pore diameter. The characteristic width was, therefore, chosen and defined as the widest width of pore rather than the diameter of the pore. The characteristic width of the pores was extracted by using image analysis software (ImageJ) on scanning electron microscope (SEM) images. Porous graphene was transferred onto SiNx chip including hole with 4 μm in diameter to make a free-standing section suitable for clear image interpretation. Five representative SEM images of porous graphene were then, taken over 1.14 um² to visualize the clear difference in the contrast between pore and surrounding graphene (e.g., black for pore and grey for graphene). As the characteristic width of pore is few tens of nm, high magnification SEM images were required. Afterward, based on the SEM image, the widest width of each pore opening was measured and the average of the measured widths subsequently calculated.

Preferably the graphene has an areal porosity (defined as the ratio of total area of pores to total projected area of the layer) of more than 2.5%, preferably of more than 5%, preferably in the range of 10-70%, and at the same time a thickness in the range of more than 1 nm, preferably of more than 2 nm, preferably in the range of 2-15 nm. The areal porosity is, generally in this document, calculated in detail as following; first, five representative SEM images of transferred highly porous graphene on the substrate were collected and a pore region was extracted using ImageJ program, typically said measurement pore region having an area of 4.6 μm².

The artificial solid-electrolyte interphase layer preferably comprises or consists of said at least one porous graphene layer and at least one additional selective graphene layer (“selective graphene layer” in this context meaning a porous graphene layer as defined above, i.e. at least one layer of porous graphene of a thickness of less than 25 nm preferably with pores having an average characteristic width as defined in the specification in the range of 1-1000 nm), wherein preferably said at least one porous graphene layer is facing said anode or current collector and the at least one additional selective graphene layer is facing said liquid state or solid-state electrolyte. Such a selective graphene layer ensures no direct contact between metallic lithium deposits and electrolyte which can prevent a formation of natural solid-electrolyte interphase, reducing a consumption of a Li or Na salt in electrolyte.

According to a preferred embodiment, such a selective graphene layer is provided in the form of a defective graphene layer, where the defects can be point defects or line defects. The defects are preferably provided in the form of atomic or grain boundary defects.

Preferably this selective graphene layer is a non-porous layer.

According to a preferred embodiment, said selective graphene layer has a thickness in the range of 0.34-5 nm, most preferably in the range of 0.34-1 nm.

The anode or current collector of, in particular an anode-free, battery can be given by an elemental metal layer or element, wherein the metal is preferably selected from the group consisting of lithium, copper, nickel, gold, silver, aluminium, or an alloy or layered composite thereof.

The anode (or current collector) is preferably an elemental metal layer of a nickel copper alloy or a ternary or quaternary alloy of nickel copper and at least one further metal selected from the group consisting of gold, silver and/or aluminium.

The at least one layer of porous graphene can be a layer grown directly on an elemental metal layer forming the anode (or current collector), providing for a particularly simple manufacturing process and a particularly stable structure, wherein the metal of said anode (or current collector) is preferably selected from copper or copper nickel alloy or layered structure or an alloy or layered structure based on copper and/or nickel and at least one further metal selected from the group consisting of gold, silver and/or aluminum. Details for a corresponding manufacturing process are given further below.

Said at least one layer of porous graphene can also be at least partially N-doped, wherein preferably the N-doping is in the form of at least one surficial N-doping and/or in the form of an N-doping of the pore boundaries. N-doped graphene includes more lithiophilic sites than bare graphene, and therefore an activation energy for Li ion to pass through and/or nucleate is reduced.

According to yet another aspect of the present invention, it proposes the use of a layer of porous graphene of a thickness of less than 25 nm preferably with pores having an average characteristic width as defined in the specification in the range of 1-1000 nm as an artificial solid-electrolyte interphase layer for a lithium or sodium-based battery.

The porous graphene layer can have the characteristics as detailed above, specifically the porous graphene layer preferably has a thickness in the range of 1-15 nm, preferably in the range of 5-10 nm, and/or the porous graphene layer has an areal porosity in the range of at least 10%, preferably at least 15%, more preferably of at least 20% or at least 25% or at least 30% or at least 40%, and/or said porous graphene has pores having an average characteristic width in the range of 5-900 nm.

According to a further aspect of the present invention, it relates to a method for making a battery according as detailed above.

Preferably, in such a method a catalytically active substrate is provided to catalyse the graphene formation under chemical vapour deposition conditions, said catalytically active substrate on its surface being provided with a plurality of catalytically inactive domains having a nanostructure essentially corresponding to the shape of the pores in the resultant porous graphene layer; chemical vapour deposition using a carbon source in the gas phase and formation of the porous graphene layer on the surface of the catalytically active substrate, the pores in the porous graphene layer being formed in situ due to the presence of the catalytically inactive domains, and wherein the catalytically active substrate with said porous graphene layer is used as an anode (or current collector) with an artificial solid-electrolyte interphase layer in the form of said porous graphene layer.

The catalytically active substrate can be a copper-nickel alloy substrate with a copper content in the range of 98 to less than 99.96% by weight and a nickel content in the range of more than 0.04 to 2% by weight, the copper and nickel contents complementing to 100% by weight of the catalytically active substrate.

The proposed method includes preferably the following elements: 1. The preparation of a specific copper/nickel alloy catalytic substrate; 2. The preparation of a topology of catalytically inactive material on top of such a catalytic substrate in the form of catalytically inactive nanostructures; 3. The synthesis of a porous graphene layer on a copper/nickel alloy catalytic substrate with such a topology of catalytically inactive nanostructures; 4. Removal of catalytically inactive nanostructures; 5. (optional) Delamination separation of the porous graphene layer if needed from the catalytic substrate, preferably by electrochemical separation methods; 6. (optional) Mechanical delamination if needed of the porous graphene layer from the catalytic substrate.

These individual steps can be carried out as follows:

1. Preparation of Cu—Ni alloy:

Cu catalyst e.g. as purchased from Alfa Aesar (Copper foil, 0.025 mm, 99.8%, Product No. 49686) is provided; a Ni film with a varied thickness from 10 nm to 2.2 μm or 50 to 300 nm is deposited on as-received commercial Cu catalyst by E-beam evaporator or sputtering in vacuum (e.g. FHR, Pentaco 100, Ni purity 99.95%3×10-3 mbar); pressure of the sputtering is about 0.006 mbar with 200 sccm of Ar; power of DC plasma is about 0.25 kW; a bi-layered structure of Ni/Cu catalyst is annealed at e.g. 1000° C. for e.g. 1 hour to convert to a binary metal alloy (Cu—Ni alloy) under low pressure (e.g. 200 mTorr) with e.g. 50 sccm of H₂ in a chemical vapor deposition (CVD) system (e.g. Graphene Square. Inc, TCVD-RF100CA).

The concentration of Ni is more than 0.04% to 10% or preferably in the range of more than 0.04 to 2% by weight, or also in the range of 0.1-10% preferably in the range of 0.2-8% or 0.3-5%, typically in the range of 0.4-3%. Particularly preferably, the catalytically active substrate has a nickel content in the range of 0.06-1% by weight or 0.08-0.8% by weight complemented to 100% by weight by the copper content. The balance is Cu (for the broadest range it is thus 99.96-90%, for a typical range it is 99.94 less than 99% or 99.6-97%, the balance does not include very minor impurities which can be present in the starting Cu foil or in the starting Ni, and which in the final substrate make up less than 0.05% or less than 0.02% by weight in total). The range of Ni content depends on the initial Ni thickness. The typical working content of Ni is preferably in the range of 0.5-2%.

2. Conversion of W Thin Film into W Nanostructures:

A thin film of W (thickness 1-10 nm) is deposited on the Cu—Ni alloy according to the preceding paragraph by sputtering or E-beam evaporator in vacuum (e.g. FHR, Pentaco 100, W purity 99.95%) with e.g. E-beam evaporator or sputtering in vacuum (e.g. 3×10⁻³ mbar); the pressure of the sputtering is e.g. 0.002 mbar with e.g. 100 sccm of Ar; the thin film of W is deposited from 1 to 10 nm with e.g. 0.25 kW of DC plasma; a W/Cu—Ni alloy is mounted in the center of a 4-inch quartz tube chamber positioned in the furnace of the CVD system (e.g. Graphene Square. Inc, TCVD-RF100CA); the chamber is evacuated to reach a pressure of e.g. 45 mTorr and then purged with inert gas, e.g. N₂ (e.g. 100 sccm) for e.g. 5 min normally at room temperature; after purging, the chamber is put under vacuum (e.g. 45 mTorr) again and then the pressure is increased e.g. with a gas mixture of Ar and H₂ (800 sccm and 40 sccm, respectively); to convert the W thin film into W nanostructures. The W nanostructures are based variously on symmetric W nanoparticles and asymmetric W nanowalls with various degrees of interparticle agglomeration. The W/Cu—Ni alloy is carefully annealed at elevated temperature (e.g. 750-950° C. or 800-900° C.) for an extended period of time, e.g. 1 hour including ramping with the continuous supply of e.g. 800 sccm of Ar and 40 sccm of H₂ under 4 Torr.

3. Synthesis of Highly Porous Graphene

Once W nanostructures (WNSs) appear in the process according to the preceding paragraph, a hydrocarbon source for example 40 sccm of methane is introduced in the chamber with e.g. 300 sccm of Ar and 40 sccm of H₂ under 4 Torr in the low-pressure CVD system; depending on the desired level of porosity or thickness, a growth duration is carefully controlled from e.g. 5 to 120 min; afterwards, the furnace is programmed to cool to room temperature under flow of Ar and H₂. Under these conditions, a total CVD time of 120 minutes leads to a graphene layer thickness of approximately 10 nm. CVD time of 5 minutes leads to a graphene layer thickness of approximately below 1 nm, but this may also depend on further parameters.

4. Removal of W Nanostructures by Pre-Leaching Method

As-grown highly porous graphene on Cu—Ni alloy is immersed in 0.1 M NaOH for 10-60 min or 15-60 min at mild temperature (40-60° C.) to remove/dissolve W NSs and decouple the bonding between highly porous graphene and the surface of Cu—Ni alloy; after the pre-leaching process, the sample can be rinsed by DI-water and dried with N₂ gas flow.

5. Electrochemical Delamination of Highly Porous Graphene Via Electrochemistry (Optional):

After pre-leaching process Poly(methyl methacrylate) (PMMA) or another material, such as a polymeric porous membrane for example polyurethane (PU; e.g. Finetex ENE) as a supporting material is assembled onto the sample as a support layer. A range of concentrations of 0.5-1.5 M NaOH proves to be suitable, lower concentrations lead to unacceptably long pre-leaching times, using higher concentrations the copper/nickel substrate will be degraded.

PMMA: PMMA (950k, AR-P 672.03) can be used; spin-coated with e.g. 4000 rpm for 40 sec.; the PMMA/highly porous graphene can be baked at 110° C. for 1 min.

Isopropyl alcohol can be applied on stacked PU/as-grown highly porous graphene on Cu—Ni alloy to achieve close interfacial attachment while drying. A melt adhesion step under controlled may also be used.

The sample and Pt electrode are connected to a respective anode and cathode of power supply (e.g. GW Instek, GPR-3060D) for example in aqueous NaOH solution (1 M).

The highly porous graphene with the supporting material can then be delaminated from the designed catalyst via H₂ bubbles electrochemically generated between an interface of the highly porous graphene and a surface of the catalyst by applying a voltage (3-10 V).

Recycling of the Catalytic Substrate:

After the process of electrochemical delamination, the Cu—Ni alloy can be re-used to grow highly porous graphene, repeatably.

6. Mechanical Delamination of Highly Porous Graphene (Optional):

After pre-leaching step, the sample can be directly attached to for example an adhesive tape for example thermal release tape (e.g. REVALPHA, Nitto Denko) or a water-soluble tape by lamination or pressing tool at room temperature to improve the adhesion; the adhesive tape is mechanically delaminated from the catalyst together with the adhered highly porous graphene.

Recycling of the Catalytic Substrate (Optional):

After the process of mechanical delamination, the Cu—Ni alloy can be re-used to grow highly porous graphene, repeatably.

For the method of producing the graphene layer the disclosure of the application PCT/EP2020/084050 is specifically included by reference into this disclosure.

Before use of the catalytically active substrate with said porous graphene layer as the anode (or current collector) of the battery said porous graphene layer can be N-doped, preferably by subjecting the graphene layer to treatment with non-inert nitrogen-containing gas, preferably in the form of ammonia gas.

Before use of the catalytically active substrate with said porous graphene layer as the anode (or current collector) of the battery on top of said porous graphene layer additionally or alternatively an additional selective, preferably non-porous graphene layer can be deposited, preferably in the form of a contiguous graphene layer having grain boundary defects.

Unexpectedly it was found that using such a catalytically active substrate alloy it is possible to make thin graphene layers having optimal porosity for battery applications. Without being bound to any theoretical explanation, it appears that this particular alloy allows the provision of particular topologies of catalytically inactive domains on the surface thereof and as a result of this topological structure allows the making of thicker graphene layers with superior gaseous permeation and liquid barrier properties.

According to a first preferred embodiment of the proposed method, the catalytically active substrate has a nickel content in the range of 0.06-1% by weight or 0.08-0.8% by weight.

The catalytically active substrate can for example be prepared by applying, preferably using electrochemical plating, e-beam evaporation, PVD or sputtering, a film of nickel of a thickness in the range of 0.01-2.2 μm, preferably in the range of 10-300 or 20-500 nm, preferably in the range of 10-300 or 50-300 nm on a pure copper foil, preferably having a thickness in the range of 0.005-0.10 mm or 0.02-2 mm, preferably in the range of 0.01-0.04 mm, in particular having a purity of more than 99.5%. Subsequently this structure is subjected to a step of annealing, preferably at a temperature in the range of 800-1200° C., preferably in the range of 900-1100° C., in particular during a time span of 5 minutes-120 minutes, preferably during a time span in the range of 10 min-60 min or 30 minutes-90 minutes.

The porous graphene layer preferably has a thickness in the range of less than 50 nm, preferably in the range of 1-20 nm, in particular in the range of 5-15 nm or 7-12 nm.

For the preferred nickel concentration, the corresponding graphene preferably has an areal porosity (defined as the ratio of total area of pores to total projected area of the layer) of more than 2.5%, preferably of more than 5%, preferably in the range of 10-70%, and at the same time a thickness in the range of more than 1 nm, preferably of more than 2 nm, preferably in the range of 2-15 nm. Further preferably the porous graphene layer has an areal porosity, defined as the areal fraction of pore space in the total graphene layer, in the range of at least 10%, preferably at least 15%, more preferably of at least 20% or at least 25%, or at least 40%.

According to yet another preferred embodiment, the catalytically active substrate is provided on its surface with a plurality of catalytically inactive domains by applying, preferably using sputtering, e-beam evaporation or PVD, an essentially contiguous tungsten layer. Preferably this tungsten layer has a thickness in the range of more than 1 nm, preferably more than 3 nm, more preferably more than 5 nm, or in the range of 1-10 nm, preferably in the range of 5-10 nm. Subsequently this structure is subjected to a step of annealing at a pressure below normal pressure, preferably of less than 100 mTorr or less than 4 Torr, in particular under a reducing atmosphere, preferably in the presence of an inert gas such as argon or nitrogen gas, combined with hydrogen gas, to convert the tungsten film into a plurality of catalytically inactive domains. Typically the annealing takes place at a temperature in the range of 700-1100° C., more preferably in the range of 750-950° C. or 800-900° C., typically during a time span in the range of 10-180 minutes, preferably in the range of 10-60 min or 50-100 minutes.

According to a preferred embodiment the method is adapted such as to obtain catalytically inactive domains having an average characteristic width in the range between 1-1000 nm, preferably in the range of 10-100 nm, more preferably in the range of 10-50 nm, or preferably having an average characteristic width in the range between 5-900 nm, preferably in the range of 10-200 nm, more preferably in the range of 10-100 nm.

The step of chemical vapour deposition to form the graphene layer can be carried out using a carbon source in the gas phase under formation of the porous graphene layer on the surface of the catalytically active substrate, the pores in the graphene layer in situ being formed due to the presence of the catalytically inactive domains, using methane gas as carbon source, preferably in the co-presence of argon and hydrogen gas under reduced pressure, preferably below 50 Torr, preferably below 5 Torr, during a time span of preferably in the range of 10-120 minutes, preferably below 60 minutes, more preferably below 50 minutes, most preferably below 35 minutes. This graphene layer deposition process preferably takes place during a time span allowing for the generation of a graphene layer of average thickness of more than 5 nm, preferably in the range of 8-12 nm.

The porous graphene layer can be optionally removed from the catalytic substrate, preferably in that for removal of the graphene layer first a supporting carrier layer is applied to the graphene layer on the surface opposite to the catalytic substrate and the sandwich of this carrier layer and graphene is removed from the catalytic substrate, and then this structure can be directly or indirectly applied to the desired anode (or current collector) material.

Prior to removal of the graphene layer, the layered structure of the catalytic substrate with the catalytically inactive domains and the as-grown graphene layer can be preferably subjected to a pre-leaching process weakening or removing the bond between the graphene layer and the catalytic substrate and/or the catalytically inactive domains.

Preferably this pre-leaching step includes the formation of an oxide layer at least partially, preferably essentially completely between the graphene layer and the catalytic substrate and the removal of the catalytically inactive domains.

The pre-leaching step can be carried out by subjecting the substrate with the graphene layer to a basic or acidic environment, preferably in water, more preferably at a pH of less than 6 or more than 7, preferably more than 10, more preferably at a pH of more than 12.

Most preferably for the pre-leaching an aqueous solution of 0.01-0.5 M NaOH is used, preferably for a time span in the range of 10-60 minutes at a temperature in the range of 40-60° C., optionally followed by rinsing with water and drying.

The graphene layer can also be removed, preferably after a pre-leaching step, using electrochemical methods, e.g. by immersing the layered structure of the catalytic substrate with the catalytically inactive domains and the graphene layer in an electrolyte and applying electrochemical potential to the substrate relative to a counter electrode in the same electrolyte.

### BRIEF DESCRIPTION OF THE DRAWINGS

Preferred embodiments of the invention are described in the following with reference to the drawings, which are for the purpose of illustrating the present preferred embodiments of the invention and not for the purpose of limiting the same. In the drawings,

FIG. 1 shows a schematic representation of a battery according to the invention;

FIG. 2 shows in a) from top to bottom a schematic representation of a charging process in a battery according to the prior art with formation of dendritic structures; in b) from top to bottom a schematic representation of a charging process in a battery according to the invention with an artificial solid electrolyte interphase layer;

FIG. 3 shows an SEM image of a porous graphene layer atop a metal alloy, in which after a pre-leaching process, a surface of the metal alloy was exposed through pores in the porous graphene layer;

FIG. 4 shows in a) a schematic representation of an artificial solid electrolyte interphase layer consisting of a porous graphene layer and a defective graphene layer in a top (top representation) and cut (bottom representation) view, and in b) an SEM image of such a structure, in which a selective graphene layer is covering a porous graphene layer;

FIG. 5 shows, in each case in a top (top representation) and cut (bottom representation) view, in a) a layer of N-doped highly porous graphene with surficial doping and in b) a layer of N-doped highly porous graphene with N-doping on the pore boundaries;

FIG. 6 shows in a) a copper metal current collector, in b) a current collector with a copper-base layer and surficial nickel layer, in c) a current collector with a copper/nickel alloy base layer and a surficial layer of gold, silver or aluminium or an alloy thereof, in d) a current collector of copper/nickel alloy and in e) a ternary metal alloy current collector, e.g. based on copper, nickel and gold or silver;

FIG. 7 schematically shows in a) the charging process for an anode in a battery with a single artificial solid-electrolyte interphase layer from left to right and in b) another charging process for an anode in a battery with an artificial solid-electrolyte layer comprising a porous graphene layer and a selective graphene layer;

FIG. 8 schematically shows in a) the charging process for an anode in a battery with a single artificial solid-electrolyte interphase layer having an N-doped bottom part from left to right and in b) another charging process for an anode in a battery with a single artificial solid-electrolyte layer on a ternary elemental metal layer;

FIG. 9 shows in a) a SEM image of free-standing highly porous graphene on SiNx membrane, clearly showing the planar porous structure and in b) an AFM image of highly porous graphene on SiO₂/Si substrate, indicating greater than 10-nm thick film;

FIG. 10 shows a SEM image of a porous graphene layer transferred on Cu foil, showing bi-continuous graphene and planar porous structure;

FIGS. 11a-11e show in a) galvanostatic Li plating/stripping voltage profiles for the Li∥Cu and Li∥highly porous graphene/Cu asymmetric cells at a fixed current density of 0.5 mA/cm² and a capacity of 0.5 mAh/cm²; in b) magnified cycling performance of the Li∥Cu and Li∥highly porous graphene/Cu asymmetric cells (from 0 to 400 hours); in c) magnified cycling performance of Li∥highly porous graphene/Cu asymmetric cell from 300 to 500 hours, in d) from 1000 to 1200 hours, and in e) from 2400 to 2600 hours.

### DESCRIPTION OF THE INVENTION

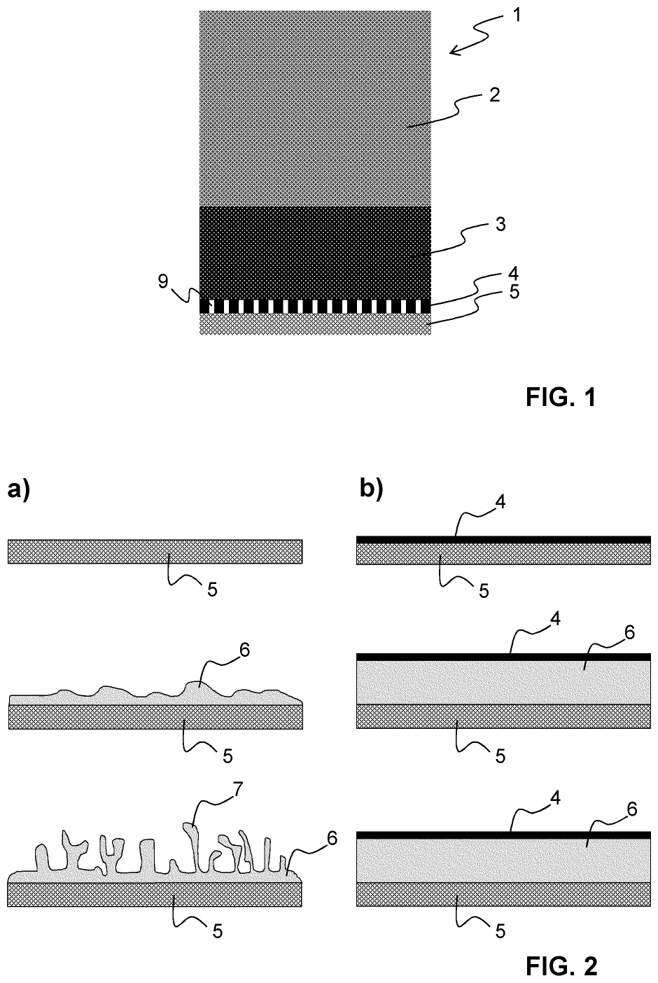

FIG. 1 shows a schematic representation of a anode-free battery 1 according to the invention. The cathode 2, which for example can be, but not limited to, a lithium sulphide (Li₂S)y, an air, a lithium iron phosphate (LiFePO₄), a lithium nickel cobalt aluminum oxide (LiNiCoAlO₂), a lithium nickel manganese cobalt oxide (LiNiₓMn_{y}Co_{z}O₂), is followed by the electrolyte 3. This electrolyte 3 may be a liquid electrolyte comprising or consisting of lithium salt such as, but not limited to, a lithium hexafluorophosphate (LiPF₆) or a lithium tetrafluoroborate (LiBF₄), in an organic solvent, such as, but not limited to, ethylene carbonate, dimethyl carbonate, or diethyl carbonate, or it may be a solid electrolyte, which for example can be a polymer, a oxide-based, or sulphide-based solid electrolyte material. On the bottom there is provided the actual anode or current collector 5 in the form of a metal layer. Between the current collector 5 and the electrolyte layer 3 having either liquid electrolyte with separator or solid-state electrolyte there is provided an artificial solid-electrolyte interphase layer 4 in the form of a graphene layer having the desired properties, in particular the porosity as discussed above. So in this graphene layer 4 there are provided pores 9.

FIG. 2 shows in a) from top to bottom a schematic representation of a charging process in an anode-free battery according to the prior art with formation of dendritic structures. In this case, the current collector illustrated in the top representation during the charging process will be covered on the upper side facing the electrolyte material by a layer of deposited elemental lithium in case of a lithium battery. As described above, and as illustrated in the bottommost representation, over time this deposition does not take the form of a stratified layer deposition but it forms dendritic structures 7 which can reach considerable height so as to even penetrate separator elements and/or the solid electrolyte to short-circuit the whole battery.

FIG. 2 shows in b) from top to bottom a schematic representation of a charging process in an anode-free battery according to the invention with an artificial solid-electrolyte interphase layer. In this case on top of the current collector 5 there is provided the porous graphene layer 4 as an artificial solid-electrolyte interphase layer. During the charging process the lithium is selectively deposited in the interface between this artificial solid-electrolyte interphase layer and the current collector 5, so that a stratified elemental lithium deposition in the form of layer 6 takes place. This behaviour could experimentally be verified over a large number of cycles, so using the graphene layers produced as detailed above batteries were assembled using these layers as artificial solid-electrolyte interphase layers and no dendritic structure formation could be observed even after several hundreds of charge and discharge cycles.

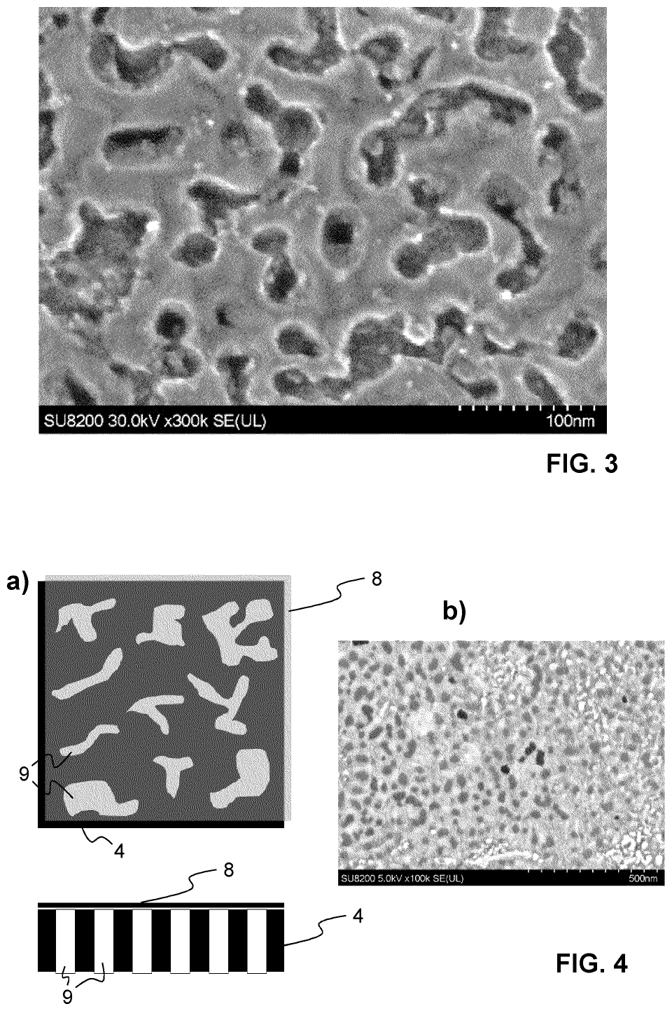

FIG. 3 shows an SEM image of a porous graphene layer 4 atop current collector 5; wherein a Cu—Ni alloy was used as the current collector 5. In the SEM image, after the pre-leaching process. The catalytically inactive W nanostructures material was completely removed, exposing the surface of the Cu—Ni alloy substrate 5. During the charging process, the lithium can penetrate the porous graphene layer 4 through pores 9 and subsequently be deposited in the interface between the porous graphene layer 4 and the current collector 5.

FIG. 4 shows in a) a schematic representation of an artificial solid-electrolyte interphase layer of a different embodiment consisting of a porous graphene layer 4 and an additional defective graphene layer 8 in a top (top representation) and cut (bottom representation) view. The defective graphene layer 8 is not porous, so it does not have the pores 9 as present in the layer 4, and it is covering in a contiguous matter layer 4. This defective graphene layer 8 prevents a natural solid-electrolyte interphase from forming, so that no lithium salt in an electrolyte will be consumed, maintaining an initial ionic conductivity; however, atomic defects such as point and/or line defects in the defective graphene layer 8 can allow passage of lithium ions through an artificial solid-electrolyte interphase consisting of a porous graphene layer 4 and an additional defective graphene layer 8. Therefore, dense and flat morphology of metallic lithium deposits appear.

FIG. 4 shows in b) an SEM picture onto such a structure. The SEM image is an example of selective graphene layer 8 atop a porous graphene 4. Most of the pores in the porous graphene 4 are covered by an additional defective graphene layer 8.

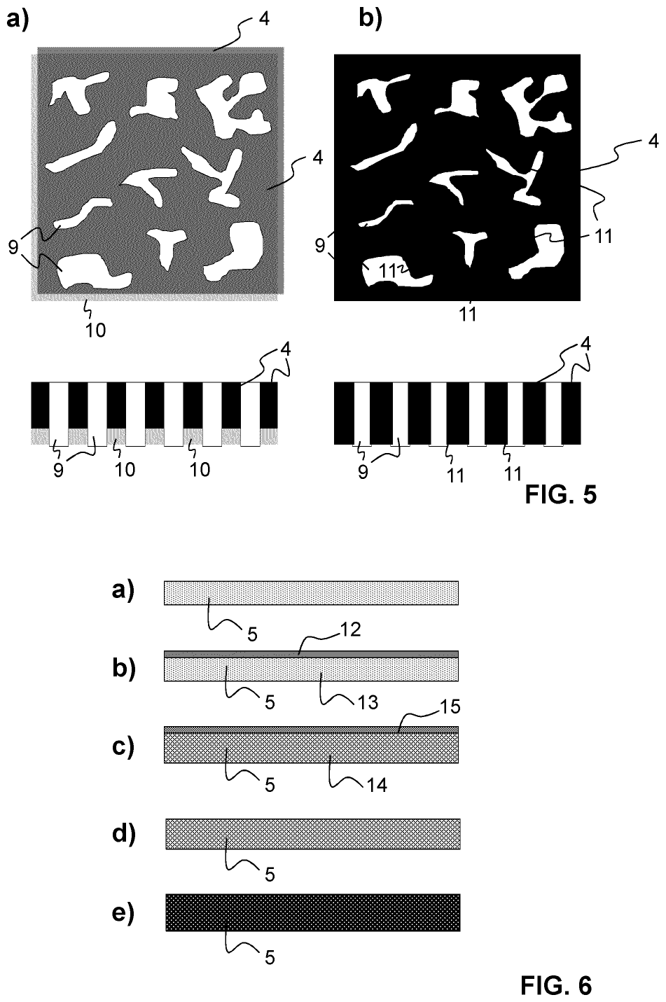

FIG. 5 shows, in each case in a top (top representation) and cut (bottom representation) view, in a) a layer of N-doped highly porous graphene with surficial doping and in b) a layer of N-doped highly porous graphene with N-doping on the pore boundaries. N-doped graphene, in particular Pyridinic N and Pyrrolic N, exhibits larger binding energy with lithium atom than bare graphene, so Li ion tends to be attracted by a N-doped site in graphene. If a bottommost layer of graphene was doped by nitrogen, a lithium ion will be guided toward the surface of the metal alloy by a gradient of lithiophilicity. Furthermore, the edge of pore was doped by nitrogen, then a lithium ion can move along the pathway of N-doped edge. Therefore, the lithium ion can arrive and be deposited on the surface of the metal alloy. This can happen because the metal alloy produced here includes more lithiophilic surface than porous graphene and N-doped porous graphene (as discussed later in the document).

As detailed above, the anode of a battery according to this invention can take the form of a lithium layer but also of another metal layer (anode free solid-state battery). In particular for the case where the anode metal layer is non-lithium and at the same time is used as the catalytic substrate for the making of the porous graphene layer, several possibilities are given for such a catalytic substrate layer which then also forms the metal anode (or current collector) of the final battery.

FIG. 6 correspondingly shows in a) a copper metal current collector which can be used as the catalytic substrate for the porous graphene interlayer synthesis process and as the current collector in the anode-free battery, in b) a current collector with a copper-base layer and surficial nickel layer taking both functions, in c) a current collector with a copper/nickel alloy base layer and a surficial layer of gold, silver or aluminum or an alloy thereof, in d) a current collector of copper/nickel alloy and in e) a ternary metal alloy current collector, e.g. based on copper, nickel and gold, silver, or aluminum. Cu is the most widely used current collector at the anode side, but overpotential for lithium nucleation is high, causing dendritic lithium formation. Although nickel is slightly favorable for a lithium ion to nucleate compared with copper, high overpotential still exists. In contrast, gold, silver, or aluminum have a solubility in a lithium metal and show negligible or low overpotential for lithium nucleation. These metals at the surface of the metal alloy produced here provide a more lithiophilic environment, thereby a lithium ion tends to be attracted and uniformly deposited on the surface leading to a dense and flat morphology of metallic Li deposits.

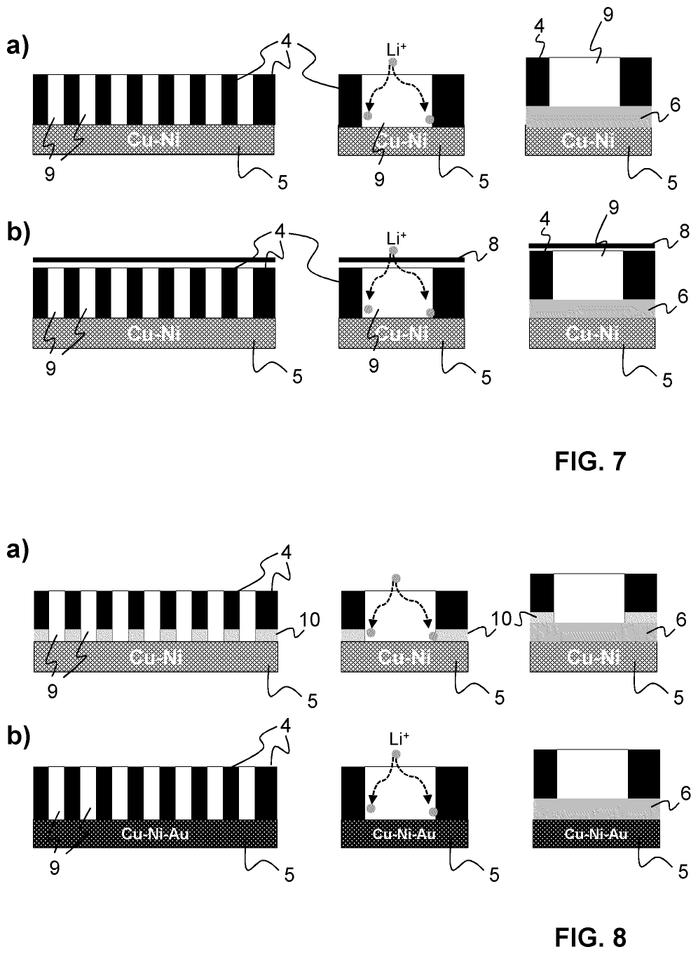

FIG. 7 schematically shows in a) the charging process for an anode in a battery with a single artificial solid electrolyte interphase layer from left to right. As schematically illustrated, the lithium ions will penetrate through the interphase layer pores in the charging process and will only deposit at the interface between the porous graphene layer 4 and the anode layer 5 forming the elemental lithium layer 6 between those 2 layers.

FIG. 7 schematically shows in b) another charging process for an anode in a battery with an artificial solid electrolyte layer comprising a porous graphene layer and a selective graphene layer. As illustrated here, one can see that the lithium ions penetrate through defects in the rather thin selective graphene layer and then deposit in the same way as illustrated in figure a) selectively in the interface region between the anode layer 5 and the porous graphene layer 4 to form the elemental lithium layer 6 without dendritic structures;

FIG. 8 schematically shows in a) the charging process for an anode in a battery with a single artificial solid electrolyte interphase layer having an N-doped bottom part 10 from left to right. As could be verified experimentally, this N-doped bottom part of the layer fosters selective deposition of elemental lithium 6 at the interface between the porous graphene layer 4 and the anode layer 5.

FIG. 8 schematically shows in b) another charging process for an anode in a battery with a single artificial solid electrolyte layer on a ternary elemental metal layer. Such a ternary metal alloy having low overpotential for a lithium ion to nucleate could allow a lithium ion to smoothly form a dense and flat metallic lithium deposit layer.

### Experimental Section

A—as-Grown Highly Porous Graphene

1. Preparation of Cu—Ni Alloy:
a. A metal catalyst (e.g. Copper foil, 0.035 mm, 99.9%, JX Nippon mining & metals) is used; a Ni film with a varied thickness from 10 nm to 2.2 μm or 50 to 300 nm is deposited on as-received Cu catalyst by E-beam evaporator or sputtering in vacuum (e.g. FHR, Pentaco 100, Ni purity 99.95%, 3×10⁻³ mbar); pressure of the sputtering is about 0.006 mbar with 200 sccm of Ar; a bi-layered structure of Ni/Cu catalyst is annealed at e.g. 1000° C. for e.g. 1 hour to convert to a binary metal alloy (Cu—Ni alloy) under low pressure (e.g. 200 mTorr) with e.g. 50 sccm of H₂ in a chemical vapor deposition (CVD) system (e.g. Graphene Square. Inc, TCVD-RF100CA).
b. The concentration of Ni is more than 0.04% to 10% or preferably in the range of more than 0.04 to 2% by weight, or also in the range of 0.1-10% preferably in the range of 0.2-8% or 0.3-5%, typically in the range of 0.4-3%. Particularly preferably, the catalytically active substrate has a nickel content in the range of 0.06-1% by weight or 0.08-0.8% by weight complemented to 100% by weight by the copper content. The balance is Cu (for the broadest range it is thus 99.96-90%, for a typical range it is 99.94 less than 99% or 99.6-97%, the balance does not include very minor impurities which can be present in the starting Cu foil or in the starting Ni, and which in the final substrate make up less than 0.05% or less than 0.02% by weight in total). The range of Ni content depends on the initial Ni thickness. The typical working content of Ni is preferably in the range of 0.5-2%.

2. Conversion of W Thin Film into W Nanostructures:
a. A thin film of W (thickness 1-10 nm) is deposited on the Cu—Ni alloy according to the preceding paragraph by sputtering or E-beam evaporator in vacuum (e.g. FHR, Pentaco 100, W purity 99.95%) with e.g. E-beam evaporator or sputtering in vacuum (e.g. 3×10⁻³ mbar); the pressure of the sputtering is e.g. 0.003 mbar with e.g. 100 sccm of Ar; the thin film of W is deposited from 1 to 10 nm with e.g. 0.25 kW of DC plasma; a W/Cu—Ni alloy is mounted in the center of a 4-inch quartz tube chamber positioned in the furnace of the CVD system (e.g. Graphene Square. Inc, TCVD-RF100CA); the chamber is evacuated to reach a pressure of e.g. 45 mTorr and then purged with inert gas, e.g. N₂ (e.g. 100 sccm) for e.g. 5 min normally at room temperature; after purging, the chamber is put under vacuum (e.g. 45 mTorr) again and then the pressure is increased e.g. with a gas mixture of Ar and H₂ (800 sccm and 40 sccm, respectively); to convert the W thin film into W nanostructures. The nanostructures are based variously on symmetric W nanoparticles and asymmetric W nanowalls with various degrees of interparticle agglomeration. The W/Cu—Ni alloy is carefully annealed at elevated temperature (e.g. 750-950° C. or 800-900° C.) for an extended period of time, e.g. 1 hour including ramping with the continuous supply of e.g. 800 sccm of Ar and 40 sccm of H₂ under 4 Torr.

3. Synthesis of Highly Porous Graphene
a. Once W nanostructures appear in the process according to the preceding paragraph, a hydrocarbon source for example 40 sccm of CH₄ is introduced in the chamber with e.g. 300 sccm of Ar and 40 sccm of H₂ under 4 Torr in the low-pressure CVD system; depending on the desired level of porosity or thickness, a growth duration is carefully controlled from e.g. 5 to 60 min; afterwards, the furnace is programmed to cool to room temperature under flow of Ar and H₂. Under these conditions, a total CVD time of 60 minutes leads to a graphene layer thickness of approximately 10 nm. CVD time of 5 minutes leads to a graphene layer thickness of approximately below 1 nm, but this may also depend on further parameters.

B—Selective Layer on Highly Porous Graphene
1. Selective graphene layer is defined as top-most graphene layer, covering porous structure in highly porous graphene, yet including point and/or line defects, for example, grain boundaries.
2. A synthesis of selective layer of graphene on highly porous graphene is performed in the CVD system. A bi-layered W/Cu—Ni alloy is annealed at an elevated temperature with e.g., 800 sccm of Ar and 40 sccm of H₂, in which a thin film of W is converted into W nanostructure according to the preceding paragraph. Once the temperature is reached (750-950° C.) and W nanostructures appear on the surface of the alloy, a hydrocarbon source, for example 40 sccm of CH₄, is introduced in the chamber with e.g. 300 sccm of Ar and 40 sccm of H₂ under 4 Torr in the low-pressure CVD system; unlike the synthesis of highly porous graphene, a growth duration is slightly prolonged, for example, for 60 min to obtain highly porous graphene plus additional 10 min to acquire a selective layer of graphene atop, but this may also depend on other parameters.

C—N-Doped Highly Porous Graphene

1. Post-Treatment—Heat Treatment
a. After the synthesis of highly porous graphene, a removal of W nanostructure is required by a pre-leaching process because W nanostructures can etch the graphene during elevated temperature annealing. The pre-leaching process is such that the as-grown sample is dipped in 0.1 M NaOH at 40° C. for 10-20 min to remove W nanostructures. Required duration of the process depends on an initial thickness of W thin film.
b. After rinsing in deionized water and drying with N₂, the pre-leached sample is re-inserted in the CVD system (e.g. Graphene Square. Inc, TCVD-RF100CA); the chamber is evacuated to reach a pressure of e.g. 45 mTorr and then purged with inert gas, e.g. N₂ (e.g. 100 sccm) for e.g. 5 min normally at room temperature; after purging, the chamber is put under vacuum (e.g. 45 mTorr) again and then the pressure is increased with H₂ (e.g. 50 sccm). The sample is carefully annealed at elevated temperature (500-1000° C.) with H₂ (e.g. 10-100 sccm) for an extended period of time, e.g. 1 hour including ramping, in which the slightly oxidized Cu—Ni surface is reduced.
c. Nitrogen-containing gas, e.g. ammonia gas (NH₃, 10-100 sccm), is introduced into the CVD system. A duration of doping step can vary depending on the amount of N-doping in highly porous graphene from 10 to 60 min. Afterwards, the furnace is programmed to cool to room temperature under flow of H₂.

2. Post Treatment—Plasma Treatment
a. After the synthesis of highly porous graphene, as-grown highly porous graphene or pre-leached highly porous graphene sample according to the preceding paragraph is placed in a plasma-equipped CVD system. The chamber is evacuated to reach a pressure of e.g. 45 mTorr and then purged with inert gas, e.g. N₂ (e.g. 100 sccm) for e.g. 5 min normally at room temperature; after purging, the chamber is put under vacuum (e.g. 45 mTorr) again and then the pressure is increased with H₂ (e.g. 50 sccm).
b. N-doped highly porous graphene can be prepared as following; 1. As-grown highly porous graphene is directly treated by nitrogen plasma, or 2. As-grown sample is treated by a combination of heat and plasma.
   i. The plasma equipped CVD system is employed in which highly porous graphene is placed in an induced coupled plasma (ICP) system; nitrogen-containing gas, for example, N₂ gas or NH₃ gas e.g., 10-100 sccm is introduced with plasma (RF power from 10 to 200 W). A duration of doping step can vary depending on the amount of N-doping in highly porous graphene from 10 to 60 min.
   ii. In order to increase the amount of N-doping level, heat and plasma treatment, which can expedite a doping process, are applied, simultaneously. The plasma equipped CVD system is employed in which an induced coupled plasma (ICP) system and a furnace are set side by side. As-grown highly porous graphene is placed in the furnace and annealed at an elevated temperature (300-1000° C.). Once the furnace is heated up, plasma is turned on (RF power from 10 to 200 W). A duration of doping step can vary depending on the amount of N-doping in highly porous graphene from 10 to 60 min. Afterwards, the furnace is programmed to cool to room temperature under flow of H₂.

3. In-Situ Treatment
a. In-situ treatment of nitrogen doping is carried out in the CVD system. A bi-layered W/Cu—Ni alloy is annealed at an elevated temperature with e.g., 800 sccm of Ar and 40 sccm of H₂, in which a thin film of W is converted into W nanostructures according to the preceding paragraph. Once the temperature is reached (750-950° C.), methane (e.g., 10-40 sccm) and ammonia (e.g., 5-40 sccm) as carbon and nitrogen source, respectively, are introduced in the chamber with e.g. 300 sccm of Ar and 40 sccm of H₂ under 4 Torr in the low-pressure CVD system; depending on the desired level of porosity, thickness, or N-doping, a growth duration and a flow rate of ammonia gas are carefully controlled from e.g. 10 to 60 min; afterwards, the furnace is programmed to cool to room temperature under flow of Ar and H₂.

D. Ternary Metal Alloy
1. Cu catalyst (e.g. Copper foil, 0.035 mm, 99.9%, JX Nippon mining & metals) is used; a Ni film with a varied thickness from 10 nm to 2.2 μm or 50 to 300 nm is deposited on as-received commercial Cu catalyst by E-beam evaporator or sputtering in vacuum (e.g. FHR, Pentaco 100, Ni purity 99.95%, 3×10⁻³ mbar); pressure of the sputtering is about 0.006 mbar with 200 sccm of Ar; the resulting film of Ni is deposited from 10 nm to 2.2 μm or 50 to 300 nm with DC plasma whose power is 0.25 kW; a Ag (or Ag, or Al) thin film with a varied thickness from 1 to 100 nm or 3.5 to 35 nm is deposited on top of the bi-layer Ni/Cu or in between Ni and Cu; the resulting film of Ag is deposited from 1 to 100 nm or 3.5 to 35 nm with E-beam evaporator (e.g. Ag purity 99.95%, 2×10⁻⁶ mbar); a tri-layered structure of Ag/Ni/Cu catalyst is annealed at e.g. 1000° C. for e.g. 1 hour to convert to a ternary metal alloy (Cu—Ni—Ag alloy) under low pressure (e.g. 200 mTorr) with e.g. 50 sccm of H₂ in a chemical vapor deposition (CVD) system (e.g. Graphene Square. Inc, TCVD-RF100CA).
2. A thin film of W (thickness 1-10 nm) is deposited on the Cu—Ni—Ag alloy according to the preceding paragraph by sputtering or E-b earn evaporator in vacuum (e.g. FHR, Pentaco 100, W purity 99.95%) with e.g. E-beam evaporator or sputtering in vacuum (e.g. 3×10⁻³ mbar); the pressure of the sputtering is e.g. 0.003 mbar with e.g. 100 sccm of Ar; the thin film of W is deposited from 1 to 10 nm with e.g. 0.25 kW of DC plasma; a W/Cu—Ni—Ag alloy is mounted in the center of a 4-inch quartz tube chamber positioned in the furnace of the CVD system (e.g. Graphene Square. Inc, TCVD-RF100CA); the chamber is evacuated to reach a pressure of e.g. 45 mTorr and then purged with inert gas, e.g. N₂ (e.g. 100 sccm) for e.g. 5 min normally at room temperature; after purging, the chamber is put under vacuum (e.g. 45 mTorr) again and then the pressure is increased e.g. with a gas mixture of Ar and H₂ (800 sccm and 40 sccm, respectively); to convert the W thin film into W nanostructures. The nanostructures are based variously on symmetric W nanoparticles and asymmetric W nanowalls with various degrees of interparticle agglomeration. The W/Cu—Ni—Ag alloy is carefully annealed at elevated temperature (e.g. 750-950° C. or 800-900° C.) for an extended period of time, e.g. 1 hour including ramping with the continuous supply of e.g. 800 sccm of Ar and 40 sccm of H₂ under 4 Torr.
3. Once W nanostructures appear in the process according to the preceding paragraph, a hydrocarbon source for example 40 sccm of methane is introduced in the chamber with e.g. 300 sccm of Ar and 40 sccm of H₂ under 4 Torr in the low-pressure CVD system; depending on the desired level of porosity or thickness, a growth duration is carefully controlled from e.g. 5 to 60 min; afterwards, the furnace is programmed to cool to room temperature under flow of Ar and H₂. Under these conditions, a total CVD time of 60 minutes leads to a graphene layer thickness of approximately 10 nm. CVD time of 5 minutes leads to a graphene layer thickness of approximately below 1 nm, but this may also depend on further parameters.

### FURTHER EXAMPLES

Catalyst Substrate Preparation:

A Cu—Ni alloy catalyst substrate was prepared to synthesize highly porous graphene. A thin film of Ni (70 nm thickness) on bare Cu foil (JX Nippon Mining & Metals) without any treatment was deposited by sputtering (FHR, Pentaco 100, Ni purity 99.95%). The deposition of Ni thin film was performed with 0.25 kW of DC power and 200 sccm of Ar under 6×10⁻³ mbar for 10 mins. The bi-layered Ni/Cu was then annealed by chemical vapor deposition (CVD) to convert it into a binary Cu—Ni alloy. The annealing process was as follows: (1) The CVD system was ramped up to 1000° C. for 60 mins with 50 sccm of H₂, (2) The temperature was sustained at 1000° C. for 15 min to complete converting the Ni/Cu into the binary metal alloy (Cu—Ni) in the presence of 50 sccm of H₂, and (3) the whole system was cooled down to room temperature at a cooling rate of 50° C./min with the same level of H₂. Subsequently, a thin film of W (6 nm) was deposited on the Cu—Ni alloy by sputtering (FHR, Pentaco 100, W purity 99.95%). The deposition of W thin film was carried out with 0.25 kW of DC power and 100 sccm of Ar under 3×10⁻³ mbar for 45 secs. The as-prepared sample including a thin film of W atop Cu—Ni alloy was inserted in the CVD system. The reactor chamber was pumped out until 45 mTorr to remove residual gases. After the pressure arrived at the base pressure, the chamber was purged out with 100 sccm of N₂ for 2 min and vacuumed down to 45 mTorr for 2 min.

Highly Porous Graphene Synthesis:

The growth process falls into two parts: (1) the W annealing step and (2) the growth step. In the annealing process, the furnace was ramped up at 750° C. for 50 mins with the continuous supply of 800 sccm of Ar and 40 sccm of H₂ under 4 Torr, followed by an additional 15-min annealing step, resulting in the conversion of W thin film into desired W nanostructures due to solid-state dewetting behavior. In the second phase of the process, the synthesis of highly porous graphene took place. Hydrocarbon precursors, such as CH₄ (40 sccm) were issued into the CVD system for 30 mins, along with 40 sccm of H₂ and 300 sccm of Ar under the same level of the process pressure. Afterward, the furnace was immediately shifted to rapidly cool down the CVD system at a cooling rate of 50° C./min in the presence of 40 sccm of H₂.

Transfer of Highly Porous Graphene onto Test Substrates:

For the preparation of highly porous graphene on various substrates (SiNx, SiO₂, and Cu foil), highly porous graphene was transferred onto a substrate of interest with the help of PMMA (950k, AR-P 672.03). A PMMA was spin-coated on the as-synthesized highly porous graphene at 4000 rpm for 60 secs. Afterward, the sample was baked at 110° C. to evaporate the solvent in the PMMA film for 1 min. The sample was then floated onto a solution of ammonium persulfate (0.5 M APS) for 3 hours to remove the metal alloy substrate, followed by a rinsing process with deionized water. The highly porous graphene supported by PMMA film was transferred onto the desired substrate and dried at room temperature. Finally, the PMMA layer was dissolved in acetone for 1 hour and the highly porous graphene on the substrate underwent a heat treatment at 350° C. for 1 hour under H₂ to remove residual PMMA and residual water molecules which can cause parasitic reactions during a battery operation. In the case of highly porous graphene transferred on SiNx membrane, the PMMA film was directly removed by a heat treatment at 400° C. in the presence of 100 sccm of H₂ and 900 sccm of Ar for 2 hours.

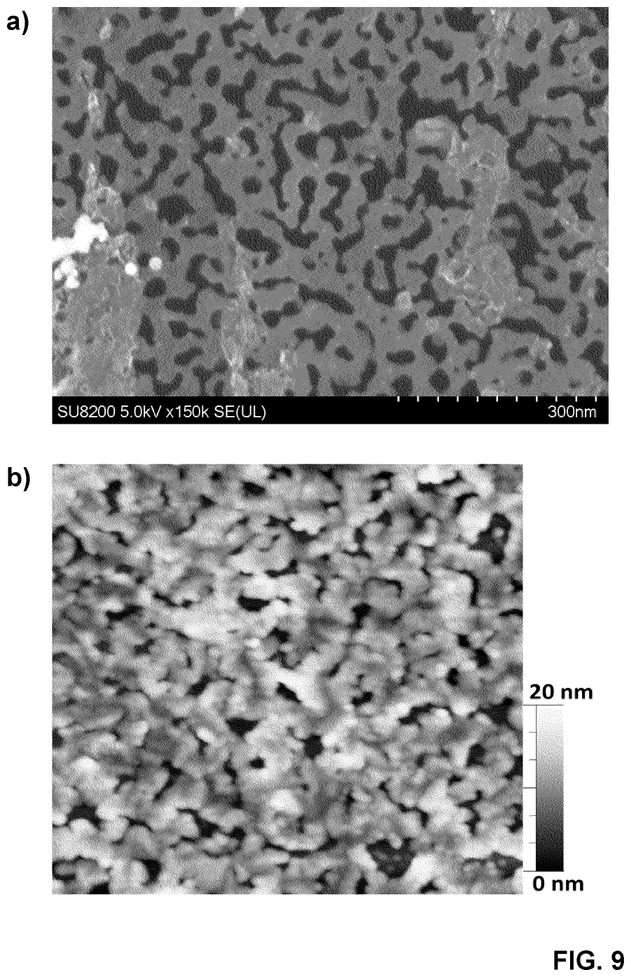

FIG. 9a shows an SEM image of the highly porous graphene transferred on SiNx. After the transfer process and subsequent heat treatment to remove the PMMA film, the planar porous structures in highly porous graphene were well maintained.

FIG. 9b an AFM image that indicates that the thickness of highly porous graphene synthesized in the abovementioned conditions is around 11 nm on average.

Battery Cell Characterization:

Li∥highly porous graphene/Cu asymmetric cells (coin cell, diameter 13 mm) were assembled, consisting of lithium metal as a reference and counter electrode and highly porous graphene/Cu foil as a working electrode.

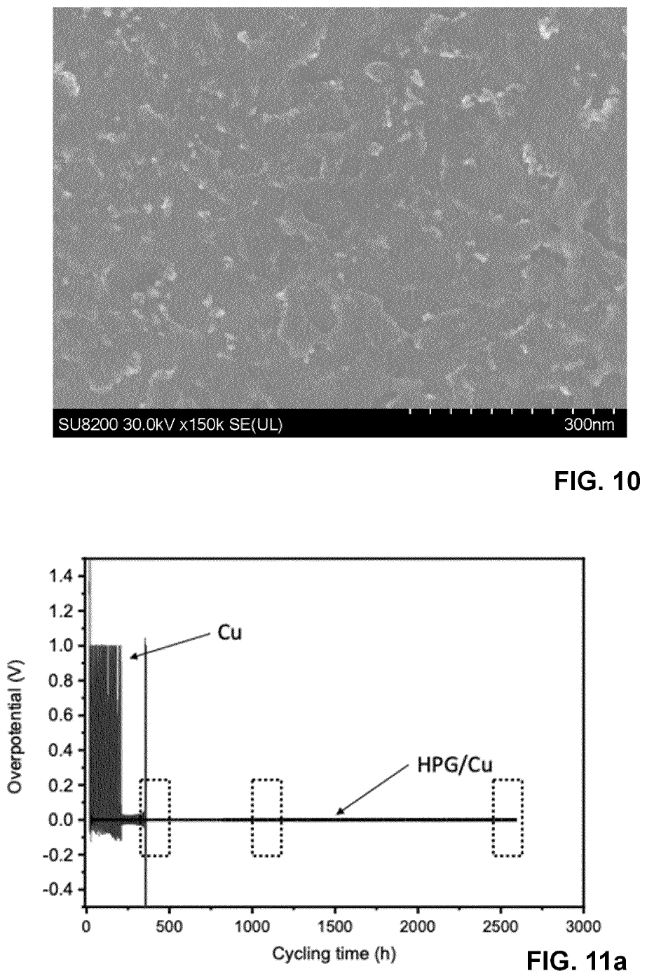

FIG. 10 is an SEM image of the highly porous graphene/Cu electrode. The electrolyte can vary depending on the battery systems, but for the experiments discussed herein, 1,2-Dimethoxyethane and 1,3-Dioxolane (DME/DOL, v/v: 1/1) solvent with 1M Lithium bis(trifluoromethanesulfonyl)imide (LiTFSI) salt and 2 wt. % LiNO₃ additive was used. A separator (Celgard 2325, 25-μm thick, polypropylene/polyethylene/polypropylene) that was soaked with the liquid electrolyte was employed between the working electrode and the counter electrode. As a reference test, Li∥Cu asymmetric cells were prepared with bare Cu foil as a working electrode, instead of highly porous graphene/Cu, and the rest of the conditions were identical. Li plating/stripping experiments were carried out on test cells constructed with either Cu or highly porous graphene/Cu. Li was plated on the corresponding working electrode at a rate of 0.5 mAh/cm².

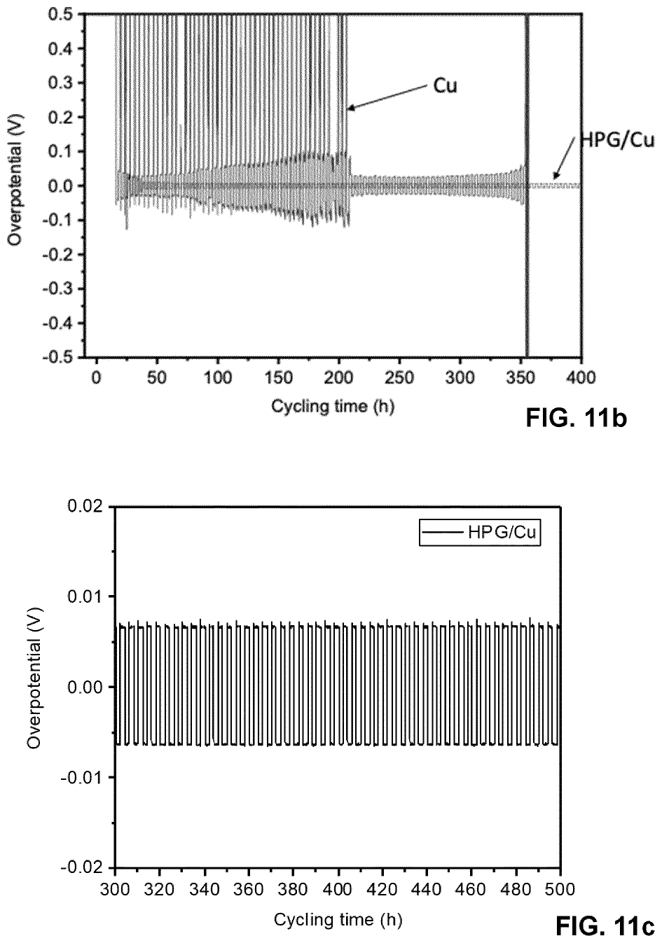

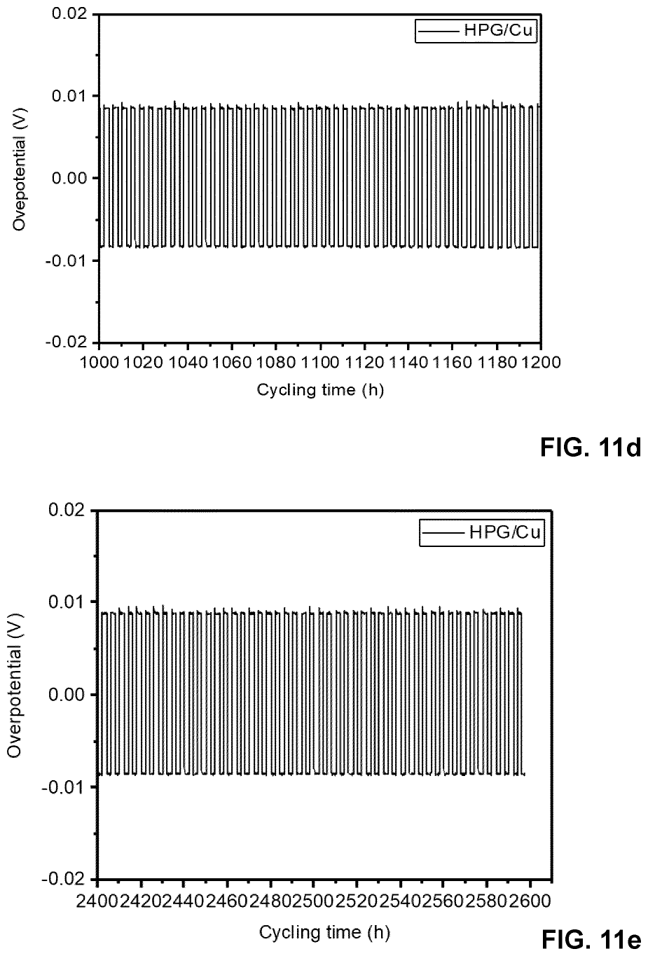

FIGS. 11a-11e show the long-term cycling properties of Li∥Cu asymmetric cells with a capacity of 0.5 mAh/cm² and a current density of 0.5 mA/cm².

As shown in FIG. 11a, the cell with the Cu foil exhibited nearly stable overpotential in the first few cycles but after 50 hours, the overpotential of the cell vastly increased with cycling and short-circuited only after 300 hours.

For the cell with the highly porous graphene/Cu, remarkably low overpotential (9 mV) remained stable over the cycles (compared to 41 mV for the bare Cu cell, shown in FIG. 11b) and this cell achieves significantly better battery performance in terms of cycle lifespan (2600 hours Vs 300 hours for the Li∥Cu asymmetric cell).

The zoomed-in plots (at 300-500, 1000-1200, and 2400-2600 hours, respectively) of Li∥Cu cell, implementing the highly porous graphene/Cu electrode, reveal negligibly increased overpotential from 7 mV to 9 mV over 2600 hours (FIG. 11c-e). The long-term stability and low overpotential suggest the highly porous graphene/Cu electrode as a stable platform of Li plating/stripping, indicating the stabilizing effect of the highly porous graphene as an ASEI layer.

1. A Li or Na based battery comprising an anode at least partially covered on its side facing the electrolyte by at least one artificial solid-electrolyte interphase layer with at least one layer of porous graphene of a thickness of less than 25 nm with pores having an average characteristic width in the range of 1-1000 nm.

2. The battery according to claim 1, wherein the artificial solid-electrolyte interphase layer has a thickness in the range of 1-15 nm,
and/or wherein the porous graphene layer has an areal porosity in the range of at least 10%,
and/or wherein said porous graphene has pores having an average characteristic width in the range of 5-900 nm,
and/or wherein the battery is a solid-state battery and the electrolyte is a solid electrolyte.

3. The battery according to claim 1, wherein the artificial solid-electrolyte interphase layer comprises or consists of said at least one porous graphene layer and at least one additional selective graphene layer.

4. The battery according to claim 3, wherein the selective graphene layer is a defective graphene layer.

5. The battery according to claim 1, wherein the anode is an elemental metal layer.

6. The battery according to claim 1, wherein the at least one layer of porous graphene is a layer grown directly on an elemental metal layer forming the anode.

7. The battery according to claim 1, wherein said at least one layer of porous graphene is at least partially N-doped.

8. A layer of porous graphene as an artificial solid-electrolyte interphase layer for a battery, the layer of porous graphene comprising a thickness of less than 25 nm with pores having an average characteristic width in the range of 1-1000 nm.

9. The layer of porous graphene according to claim 8, wherein the layer of porous graphene has a thickness in the range of 1-15 nm,
and/or wherein the porous graphene layer has an areal porosity in the range of at least 10%,
and/or wherein said porous graphene has pores having an average characteristic width in the range of 5-900 nm.

10. A method for making a battery according to claim 1, wherein a catalytically active substrate is provided to catalyse the graphene formation under chemical vapour deposition conditions, said catalytically active substrate on its surface being provided with a plurality of catalytically inactive domains having a nanostructure essentially corresponding to the shape of the pores in the resultant porous graphene layer;
chemical vapour deposition using a carbon source in the gas phase and formation of the porous graphene layer on the surface of the catalytically active substrate, the pores in the porous graphene layer being formed in situ due to the presence of the catalytically inactive domains,
and wherein the catalytically active substrate with said porous graphene layer is used as an anode with an artificial solid-electrolyte interphase layer in the form of said porous graphene layer.

11. The method according to claim 10, wherein, before use of the catalytically active substrate with said porous graphene layer as the anode of the solid-state battery, said porous graphene layer is N-doped by subjecting the graphene layer to treatment with non-inert nitrogen-containing gas.

12. The method according to claim 10, wherein, before use of the catalytically active substrate with said porous graphene layer as the anode of the battery, on top of said porous graphene layer an additional selective, non-porous graphene layer is deposited.

13. The method according to claim 10, wherein the catalytically active substrate has a nickel content in the range of 0.06-1% by weight or 0.08-0.8% by weight complemented to 100% by weight by the copper content,
and/or wherein the catalytically active substrate is prepared by applying a nickel film of a thickness in the range of 10 nm to 2.2 μm on a pure copper foil, and by annealing.

14. The method according to claim 10, wherein the catalytically active substrate is provided on its surface with a plurality of catalytically inactive domains by applying, essentially contiguous tungsten layer, and by subsequently annealing at a pressure below normal pressure, to convert the tungsten film into a plurality of catalytically inactive domains.

15. The method according to claim 10, wherein the catalytically inactive domains have an average characteristic width in the range of 1-1000 nm.

16. The battery according to claim 1, wherein the artificial solid-electrolyte interphase layer in the form of a porous graphene layer has a thickness in the range of 1-15 nm or in the range of 5-10 nm,
and/or wherein the porous graphene layer has an areal porosity in the range of at least 15%, or of at least 20% or at least 25% or at least 30% or at least 40%.

17. The battery according to claim 1, wherein the artificial solid-electrolyte interphase layer comprises or consists of said at least one porous graphene layer and at least one additional selective graphene layer, and wherein said at least one porous graphene layer is facing said anode and the at least one additional selective graphene layer is facing said electrolyte.

18. The battery according to claim 3, wherein the selective graphene layer is a defective graphene layer, having atomic defects, and wherein the selective graphene layer is a non-porous layer,
or wherein said selective graphene layer has a thickness in the range of 0.34-5 nm, or in the range of 0.34-1 nm.

19. The battery according to claim 1, wherein the anode is an elemental metal layer, wherein the metal is selected from the group consisting of lithium, copper, nickel, gold, silver, aluminium, or an alloy or layered composite thereof, including where the anode is an elemental metal layer of a nickel copper alloy or a ternary or quaternary alloy of nickel copper and at least one further metal selected from the group consisting of gold, silver and/or aluminium.

20. The battery according to claim 1, wherein the at least one layer of porous graphene is a layer grown directly on an elemental metal layer forming the anode, wherein the metal of said anode is selected from copper or copper nickel alloy or layered structure or an alloy or layered structure based on copper and/or nickel and at least one further metal selected from the group consisting of gold, silver and/or aluminium.

21. The battery according to claim 1, wherein said at least one layer of porous graphene is at least partially N-doped, wherein the N-doping is in the form of at least one surficial N-doping and/or in the form of an N-doping of the pore boundaries.

22. The method according to claim 8, wherein the porous graphene is used as an artificial solid-electrolyte interphase layer for a lithium-based or sodium-based battery, or a solid-state battery.

23. The method according to claim 8, wherein the porous graphene layer has a thickness in the range of 1 5-10 nm,
and/or wherein the porous graphene layer has an areal porosity in the range of at least 15%, or of at least 20% or at least 25% or at least 30% or at least 40%.

24. The method according to claim 10, wherein the catalytically active substrate is a copper-nickel alloy substrate with a copper content in the range of 98 to less than 99.96% by weight and a nickel content in the range of more than 0.04 to 2% by weight, the copper and nickel contents complementing to 100% by weight of the catalytically active substrate.

25. The method according to claim 10, wherein, before use of the catalytically active substrate with said porous graphene layer as the anode of the solid-state battery, said porous graphene layer is N-doped by subjecting the graphene layer to treatment with non-inert nitrogen-containing gas, including in the form of ammonia gas.

26. The method according to claim 10, wherein, before use of the catalytically active substrate with said porous graphene layer as the anode of the battery on top of said porous graphene layer an additional selective, non-porous graphene layer is deposited, in the form of a contiguous graphene layer having atomic defects.

27. The method according to claim 10, wherein the catalytically active substrate is prepared by applying, using electrochemical plating, e-beam evaporation, PVD or sputtering, a nickel film of a thickness in the range of 10 nm to 2.2 μm or in the range of 25-300 or 20-500 nm, or in the range of 50-300 nm on a pure copper foil, including the pure copper foil having a thickness in the range of 0.01-0.10 mm, or in the range of 0.02-0.04 mm, and/or having a purity of more than 99.5%, and by annealing, at a temperature in the range of 800-1200° C., or in the range of 900-1100° C., during a time span of 10 minutes-120 minutes, or during a time span in the range of 30 minutes-90 minutes.

28. The method according to claim 10, wherein the catalytically active substrate is provided on its surface with a plurality of catalytically inactive domains by applying, using sputtering, e-beam evaporation or PVD, an essentially contiguous tungsten layer, with a thickness in the range of more than 1 nm, or more than 3 nm, or more than 5 nm, or in the range of 1-10 nm, or in the range of 5-10 nm, and by subsequently annealing at a pressure below normal pressure, or of less than 100 mTorr, under a reducing atmosphere, including in the presence of an inert gas such as argon or nitrogen gas, combined with hydrogen gas, to convert the tungsten film into a plurality of catalytically inactive domains, wherein the annealing takes place at a temperature in the range of 700-1100° C., or in the range of 750-950° C. or 800-900° C., during a time span in the range of 10-180 minutes, or in the range of 50-100 minutes.

29. The method according to claim 10, wherein the catalytically inactive domains have an average characteristic width in the range of 10-100 nm, or in the range of 10-50 nm, or having an average characteristic width in the range between 5-900 nm, or in the range of 10-200 nm, or in the range of 10-100 nm
